(19) United States
(12) Patent Application Publication
(10) Pub. No.: US 2022/0319893 A1
(43) Pub. Date: Oct. 6, 2022

(54) INFORMATION ACQUISITION SYSTEM FOR SUBSTRATE PROCESSING APPARATUS, ARITHMETIC DEVICE, AND INFORMATION ACQUISITION METHOD FOR SUBSTRATE PROCESSING APPARATUS

(71) Applicant: Tokyo Electron Limited, Tokyo (JP)

(72) Inventors: Junnosuke MAKI, Koshi City (JP); Koudai HIGASHI, Koshi City (JP); Ryo KONISHI, Koshi City (JP); Hideki KAJIWARA, Koshi City (JP); Hokuto SHIGEMOTO, Koshi City (JP)

(21) Appl. No.: 17/657,194

(22) Filed: Mar. 30, 2022

(30) Foreign Application Priority Data
Mar. 31, 2021 (JP) 2021-061554
Feb. 17, 2022 (JP) 2022-022862

(51) Int. Cl. H01L 21/68; H01L 21/67; H01L 21/687

(52) U.S. Cl. CPC H01L 21/681; H01L 21/67259; H01L 21/67276; H01L 21/68785; G01B 11/026

(57) ABSTRACT

An information acquisition system is for acquiring information about a substrate processing apparatus including a substrate holder configured to hold and rotate a substrate, a nozzle configured to supply a processing liquid to a surface of the substrate which is rotating, and a cup surrounding the substrate held by the substrate holder. The information acquisition system includes: an information acquisition body held in place of the substrate by the substrate holder and including an imaging part configured to image the cup and acquire image data; and an acquisition part configured to acquire information about a height of the cup based on the image data.

### CROSS-REFERENCE TO RELATED APPLICATIONS

This application is based upon and claims the benefit of priority from Japanese Patent Application No. 2021-061554 and Japanese Patent Application No. 2022-022862, filed on Mar. 31, 2021 and Feb. 17, 2022, respectively, the entire contents of which are incorporated herein by reference.

### TECHNICAL FIELD

The present disclosure relates to an information acquisition system for a substrate processing apparatus, an arithmetic device, and an information acquisition method for a substrate processing apparatus.

### BACKGROUND

In a semiconductor device manufacturing process, a semiconductor wafer (hereinafter, referred to as a “wafer”) is transported to a substrate processing apparatus in a state of being stored in a carrier and subjected to processing. Examples of this processing include liquid processing such as formation of a coating film by supplying a coating liquid or development. During the liquid processing, a processing liquid is supplied from a nozzle to the wafer accommodated in a cup. Patent Document 1 describes a development apparatus including a cup having an annular protrusion facing the bottom surface of a wafer.

### PRIOR ART DOCUMENT

### Patent Document

Patent Document 1: Japanese Laid-Open Patent Publication No. 2020-13932

### SUMMARY

According to one embodiment of the present disclosure, there is provided an information acquisition system for acquiring information about a substrate processing apparatus, which includes a substrate holder configured to hold and rotate a substrate, a nozzle configured to supply a processing liquid to a surface of the substrate which is rotating, and a cup surrounding the substrate held by the substrate holder. The information acquisition system includes: an information acquisition body held in place of the substrate by the substrate holder and including an imaging part configured to image the cup and acquire image data; and an acquisition part configured to acquire information about a height of the cup based on the image data.

According to another embodiment of the present disclosure, there is provided an information acquisition system for acquiring information about a substrate processing apparatus, which includes a substrate holder configured to hold and rotate a substrate, a nozzle configured to supply a processing liquid to a surface of the substrate which is rotating, and a cup surrounding the substrate held by the substrate holder. The information acquisition system includes: an information acquisition body held in place of the substrate by the substrate holder and including an imaging part configured to image the nozzle and acquire image data; and an acquisition part configured to acquire a distance between the substrate and the nozzle based on a number of pixels between the nozzle in the image data and a preset reference height in the image data.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a substrate processing apparatus constituting an information acquisition system according to an embodiment of the present disclosure.

FIG. 2 is a vertical cross-sectional front view of a resist film forming module included in the substrate processing apparatus.

FIG. 3 is a plan view of the resist film forming module.

FIG. 4 is a side view illustrating a cup and a thinner supply nozzle constituting the resist film forming module.

FIG. 5 is an explanatory view illustrating an inspection wafer and an arithmetic device constituting the information acquisition system.

FIG. 6 is a plan view of the inspection wafer.

FIG. 7 is an explanatory view illustrating an image of the top surface of an annular protrusion provided on the cup.

FIG. 8 is an explanatory view for describing a preparation process for performing an inspection.

FIG. 9 is a graph which is data acquired in the preparation process.

FIG. 10 is an explanatory view for describing a preparation process for performing an inspection.

FIG. 11 is an explanatory view illustrating an image acquired in the preparation process.

FIG. 12 is an explanatory view illustrating an image of a side surface of a nozzle provided in the resist film forming module.

FIG. 13 is a vertical cross-sectional side view illustrating another example of the configuration of the cup.

FIG. 14 is a vertical cross-sectional side view illustrating another example of the configuration of the resist film forming module.

FIG. 15 is an explanatory view for describing a preparation process for performing an inspection.

FIG. 16 is an explanatory view for describing a preparation process for performing an inspection.

FIG. 17 is an explanatory view for describing a preparation process for performing an inspection.

FIG. 18 is an explanatory diagram for describing detection of the height of an intermediate guide part constituting the resist film forming module.

FIG. 19 is a plan view illustrating another example of the inspection wafer and the cup.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

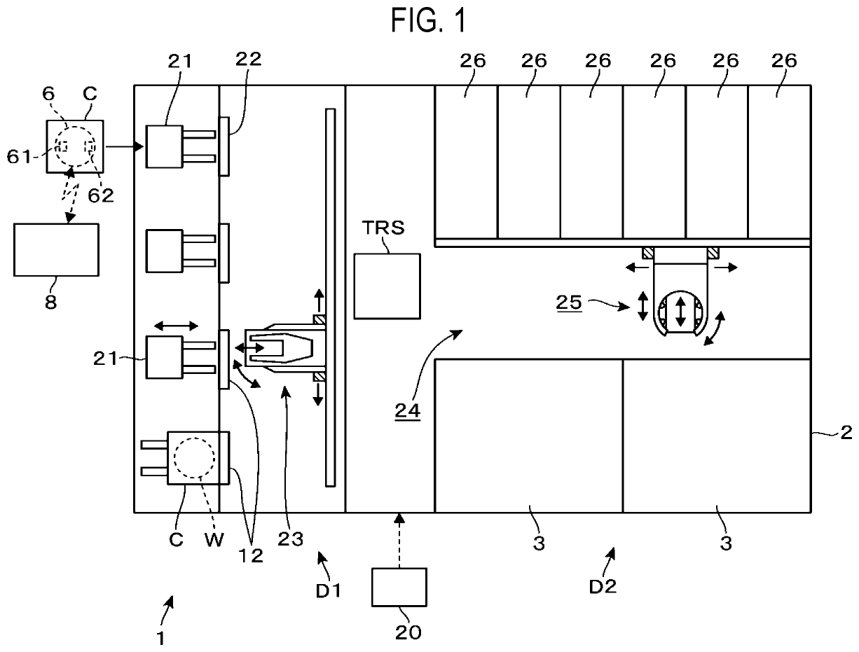

FIG. 1 illustrates an information acquisition system 1 according to an embodiment of the present disclosure. The information acquisition system 1 includes a substrate processing apparatus 2, an inspection wafer 6, and an arithmetic device 8. First, an outline of each part constituting the information acquisition system 1 will be described. The above-described substrate processing apparatus 2 transports a wafer W, which is a circular substrate, between processing modules by a transport mechanism to perform processing of the wafer W. This processing includes supplying a resist to the wafer W stored in a cup to form a resist film in a processing module for forming a resist film.

The inspection wafer 6 is transported to the substrate processing apparatus 2 in place of a wafer W by the above-described transport mechanism. Then, each of an annular protrusion constituting the cup and a nozzle is imaged to acquire image data. This nozzle is a nozzle for edge bead removal (EBR). The EBR is a process for restrictively removing, from a film (a resist film in the present embodiment) formed on the entire surface of a wafer W by ejecting a solvent from the nozzle, a portion covering the peripheral edge portion of the wafer W.

Based on the image data and data acquired in advance, the arithmetic device 8 acquires each of information about a distance between a wafer W and the annular protrusion when the wafer W is placed in the above-described processing module and information about a distance between the wafer W and the nozzle for EBR. By acquiring the information of these distances before the processing of the wafer W by the substrate processing apparatus 2, it is possible to prevent the processing when forming a resist film on the wafer W from becoming abnormal.

Hereinafter, the substrate processing apparatus 2 will be described in detail. The substrate processing apparatus 2 includes a carrier block D1 and a processing block D2. The carrier block D1 and the processing block D2 are arranged side by side and connected to each other. The wafer W is transported to the carrier block D1 by a transport mechanism (not illustrated) for a carrier C in the state of being stored in the carrier C, which is a transport container. The carrier block D1 includes a stage 21 on which the carrier C is placed. In addition, the carrier block D1 is provided with an opening/closing part 22 and a transport mechanism 23. The opening/closing part 22 opens/closes a transport port formed on the side wall of the carrier block D1. The transport mechanism 23 transports a wafer W to the carrier C on the stage 21 through the above-described transport port.

The processing block D2 includes a transport path 24 of a wafer W extending in the left-right direction, and a transport mechanism 25 provided in the transport path 24. A wafer W is transported between the carrier C and each processing module provided in the processing block D2 by the transport mechanism 25 and the above-described transport mechanism 23. Processing modules are provided side by side on each of the front side and the rear side of the transport path 24. The processing modules on the rear side are heating modules 26, which perform a heating process for removing the solvent in a resist film. The processing modules on the front side are resist film forming modules 3. In addition, a delivery module TRS in which a wafer W is temporarily placed is provided in the transport path 24 at a position near the carrier block D1. A wafer W is delivered between the carrier block D1 and the processing block D2 via the delivery module TRS.

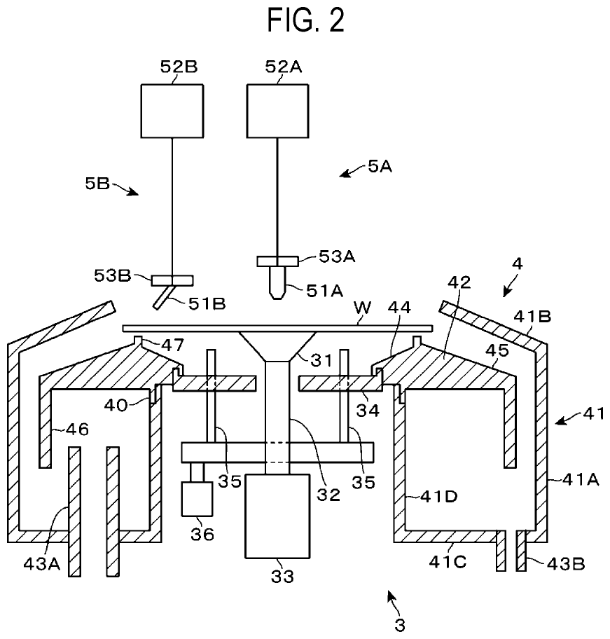

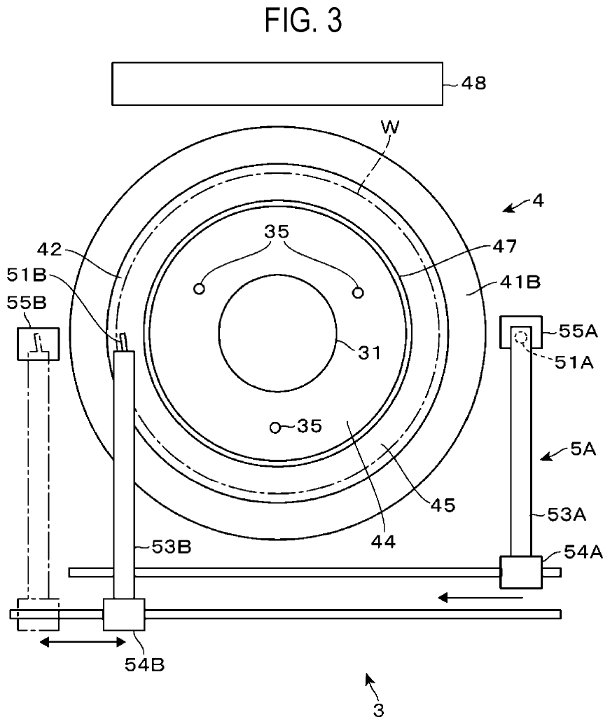

Subsequently, the resist film forming module 3 will be described with reference to the vertical cross-sectional side view of FIG. 2 and the plan view of FIG. 3. The resist film forming module 3 includes a spin chuck 31 which is a substrate holder, and the spin chuck 31 attracts the central portion on the rear surface of the wafer W and holds the wafer W horizontally. The spin chuck 31 is connected to the rotation mechanism 33 via a shaft 32 extending vertically, and the wafer W held on the spin chuck 31 rotates around the vertical shaft by the rotation mechanism 33. In addition, a protective plate 34 surrounding the shaft 32 is provided, and three lifting pins 35 extending in the vertical direction to penetrate the protective plate 34 are provided (only two are illustrated in FIG. 2). The lifting pins 35 move upward and downward by the lifting mechanism 36, and the wafer W is delivered between the spin chuck 31 and the above-described transport mechanism 25.

A circular cup 4 is provided to surround the wafer W from the lower side to the lateral side of the peripheral edge of the wafer W held by the spin chuck 31, and the cup 4 includes a cup main body 41 and a guide part 42. The cup main body 41 includes an outer cylindrical portion 41A, an inclined portion 41B, a bottom main body 41C, and an inner cylindrical portion 41D. The outer cylindrical portion 41A is a member that stands up and is disposed outside the wafer W, and the top edge of the outer cylindrical portion 41A extends diagonally toward the upper side of the center side of the cup 4 to form the inclined portion 41B. The inclined portion 41B surrounds the side circumference of the wafer W.

The lower end of the outer cylindrical portion 41A is directed toward the center side of the cup 4, so that the bottom main body 41C is formed, and the inner peripheral edge of the bottom main body 41C is directed upward, so that the inner cylindrical portion 41D is formed. The inner cylindrical portion 41D is positioned closer to the outside of the cup 4 than the peripheral edge of the protective plate 34. The outer cylindrical portion 41A, the bottom main body 41C, and the inner cylindrical portion 41D formed as described above form an annular recess along the periphery of the wafer W, and the processing liquid dropped or scattered from the wafer W can be received by the recess. The bottom main body 41C is provided with an exhaust pipe 43A for evacuating the interior of the cup 4, and an exhaust port 43B for draining the processing liquid from the recess is opened in the bottom main body 41C.

Next, the guide part 42, which is a lower member, will be described. The guide part 42 is a member that is formed to spread from the upper portion of the peripheral edge of the above-described protective plate 34 toward the outer cylindrical portion 41A and forms an annular shape in a plan view. The guide part 42 is positioned below the wafer W held by the spin chuck 31. A lower annular protrusion 40 in contact with the inner peripheral surface of the inner cylindrical portion 41D is provided below the guide part 42 and configured such that no gap is formed between the inner cylindrical portion 41D and the guide part 42 and the processing liquid does not leak to the outside of the cup 4.

The top surface of the guide part 42 is formed as inclined surfaces 44 and 45, and the inclined surface 44 is positioned closer to the center of the cup 4 than the inclined surface 45. The inclined surface 44 rises toward the outside of the cup 4, and the inclined surface 45 descends toward the outside of the cup 4, so that the vertical cross section of the guide part 42 is formed in a mountain shape. The peripheral edge of the guide part 42 is positioned away from the inner peripheral surface of the outer cylindrical portion 41A and protrudes downward to form a vertical portion 46. The vertical portion 46 and the inclined surface 45 have a role of guiding the processing liquid (resist and solvent) that has adhered thereto by falling or scattering from the wafer W such that the processing liquid flows down to the bottom main body 41C.

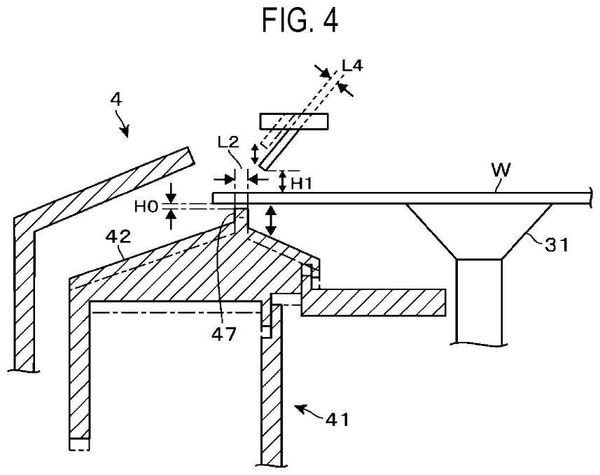

As the slope become steeper at each of the peripheral end portion of the inclined surface 44 near the outside of the cup 4 and the peripheral end portion of the inclined surface 45 near the center side of the cup 4, an annular protrusion 47 is formed. That is, the annular protrusion 47 is formed to protrude upward, and is positioned close to the peripheral edge of the wafer W by extending along the circumference of the wafer W placed on the spin chuck 31 described above. The annular protrusion 47 prevents the processing liquid supplied to the front surface of the wafer W from going around to the rear surface of the wafer W and then adhering to a position in the vicinity of the center of the wafer W, or prevents mists of the processing liquid from adhering to a position in the vicinity of the center of the rear surface of the wafer W. For example, as illustrated in FIG. 4, the height at which the guide part 42 is installed is adjustable with respect to the cup main body 41. Therefore, the relative height between the wafer W and the annular protrusion 47 with respect to the spin chuck 31 supporting the wafer W is adjustable. The distance between the rear surface of the wafer W and the upper end of the annular protrusion 47 is referred to as a cup separation distance H0, as illustrated in FIG. 4.

Next, a resist supply mechanism 5A and an EBR processing mechanism 5B provided in the resist film forming module 3 are described. The resist supply mechanism 5A includes a resist supply nozzle 51A, a resist supply part 52A, an arm 53A, a moving mechanism 54A, and a standby part 55A. The resist supply nozzle 51A ejects the resist pressure-fed from the resist supply part 52A vertically downward. The arm 53A supports the resist supply nozzle 51A and is configured to move horizontally and move up and down by the moving mechanism 54A. A standby part 55A that opens upward is provided outside the cup 4, and the resist supply nozzle 51A moves between the inside of the opening of the standby part 55A and the inside of the cup 4 by the moving mechanism 54A. The resist supply nozzle 51A moved into the cup 4 ejects the resist onto the center portion of the rotating wafer W, and a resist film is formed on the entire front surface of the wafer W by spin coating.

The EBR processing mechanism 5B includes a solvent supply nozzle 51B, a solvent supply part 52B, an arm 53B, a moving mechanism 54B, and a standby part 55B. The solvent supply nozzle 51B is an EBR nozzle and ejects the solvent pressure-fed from the solvent supply part 52B obliquely downward from the center side of the wafer W to the peripheral end side. That is, the solvent is ejected in a direction inclined with respect to the vertical direction. The arm 53B supports the solvent supply nozzle 51B, and is configured move horizontally and move up and down by the moving mechanism 54B. A standby part 55B that opens upward is provided outside the cup 4, and the solvent supply nozzle 51B moves between the inside of the opening of the standby part 55B and the processing position above the wafer W inside the cup 4 by the moving mechanism 54B. FIG. 3 illustrates the solvent supply nozzle 51B in the state of being moved to the processing position by a solid line, and the above-described EBR is performed by ejecting the solvent from the solvent supply nozzle 51B at the processing position with respect to the rotating wafer W.

For example, the solvent supply nozzle 51B is installed such that the height thereof is adjustable with respect to the arm 53B. Therefore, a distance H1 between the solvent supply nozzle 51B and the front surface of the wafer W at the processing position illustrated in FIG. 4 (referred to as a “nozzle separation distance”) is adjustable. By changing the nozzle separation distance H1, the landing position of solvent ejected from the solvent supply nozzle 51B on the wafer W changes. Although illustrated only in FIG. 3, an illumination part 48 capable of emitting light toward the cup 4 is provided in the vicinity of the cup 4. When the solvent supply nozzle 51B is imaged, which will be described later, the illumination part 48 emits light to the solvent supply nozzle 51B.

The substrate processing apparatus 2 includes a controller 20 configured with a computer (see FIG. 1), and is installed with a program stored in a storage medium such as a compact disk, a hard disk, a memory card, or a DVD. Instructions (respective steps) are incorporated in the program such that a control signal is output to each part of the substrate processing apparatus 2 by the installed program. Then, by this control signal, the wafer W is transported by the transport mechanisms 23 and 25, and the wafer W is processed by each processing module.

Due to an error during assembly or adjustment of the resist film forming module 3 by an operator, the cup separation distance H0 which is a first distance and/or the nozzle separation distance H1 which is a second distance may be out of an appropriate range. When the wafer W is processed in the state in which the cup separation distance H0 is inappropriate, the annular protrusion 47 comes into contact with the wafer W and damages the rear surface of the wafer W, or the annular protrusion 47 may be excessively spaced apart from the wafer W such that its function may not be sufficiently achieved. In addition, when the wafer W is processed in the state in which the nozzle separation distance H1 is inappropriate, the width of the region from which the resist film is removed becomes abnormal. In order to prevent the occurrence of such problems in advance, as described above, in the information acquisition system 1, image data of the annular protrusion 47 and the solvent supply nozzle 51B are acquired, and the cup separation distance H0 and the nozzle separation distance H1 are acquired as distance information from the image data.

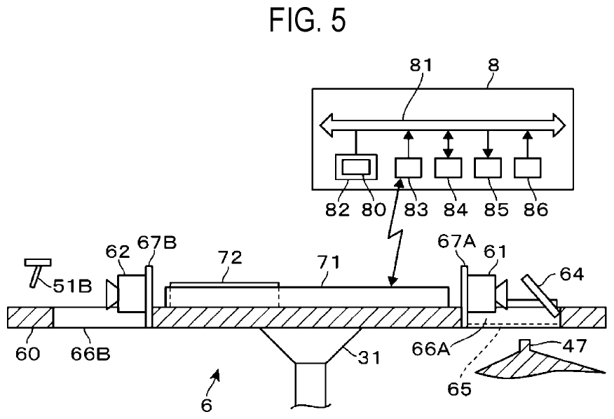

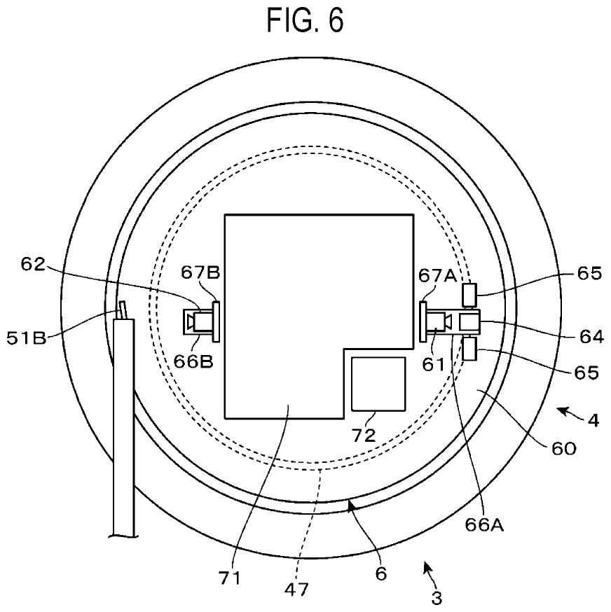

Hereinafter, the configuration of an inspection wafer 6, which is an information acquisition body used for acquiring image data, will be described with reference to a side view of FIG. 5 and a plan view of FIG. 6. The inspection wafer 6 includes a main body 60, a first camera 61, a second camera 62, a mirror 64, an illumination part 65, a device mounting board 71, and a battery 72. The main body 60 is a circular substrate having the same size as the wafer W in a plan view. The first camera 61, the second camera 62, the mirror 64, the illumination part 65, the device mounting board 71, and the battery 72 are provided on the main body 60. The main body 60 is transported by the transport mechanisms 23 and 25 and the lifting pins 35 of the module in the same manner as the wafer W, and the bottom surface thereof is configured as a flat surface like the bottom surface of the wafer W such that the central portion of the rear surface is attracted and held by the spin chuck 31. FIGS. 5 and 6 illustrate the inspection wafer 6 in the state of being held by the spin chuck 31 in this manner.

In the peripheral edge of the main body 60, through holes 66A and 66B are formed at positions separated from each other in the circumferential direction of the main body 60. At positions near the center of the main body 60 in the through holes 66A and 66B, upright boards 67A and 67B are installed on the peripheral surfaces forming the through holes 66A and 66B. The boards 67A and 67B protrude upward from the through holes 66A and 66B, respectively. The first camera 61 and the second camera 62 are provided on the boards 67A and 67B, respectively, to be capable of imaging the upper side of the main body 60. The fields of view of the first camera 61 and the second camera 62, which are imaging parts, are directed toward the peripheral end of the main body 60.

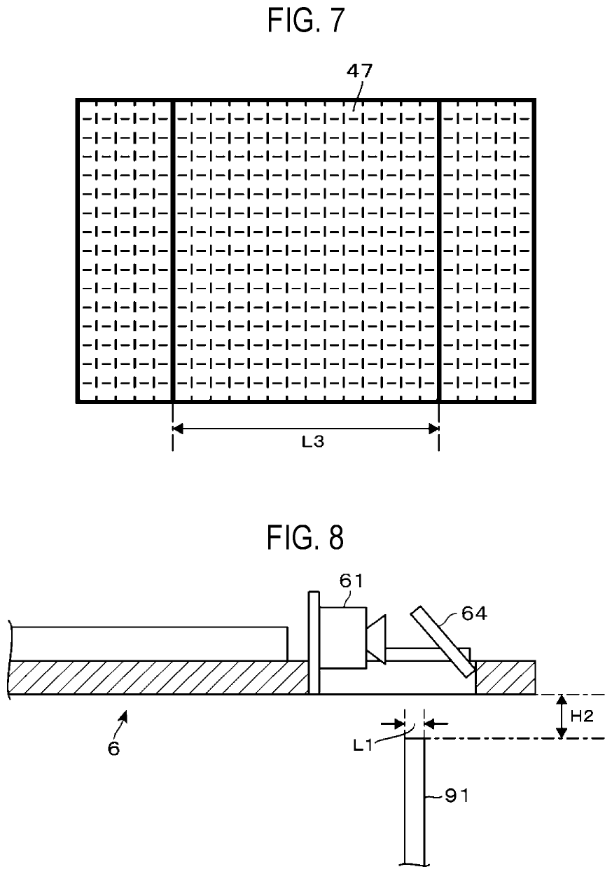

A mirror 64 is disposed on the optical axis of the first camera 61, and the mirror 64 images the lower side of the main body 60 through the through hole 66A. Therefore, the first camera 61 is capable of imaging the lower side of the main body 60 through the through hole 66A and the mirror 64. When the inspection wafer 6 is held by the spin chuck 31, the mirror 64 is positioned above the annular protrusion 47, and the first camera 61 may image a portion of the top surface of the annular protrusion 47 in the circumferential direction. FIG. 7 schematically illustrates an example of image data acquired by the imaging, and a frame surrounded by the dotted lines in the drawing represents one pixel.

In addition, two illumination parts 65 are embedded in the main body 60. Respective illumination parts 65 are positioned with the through hole 66A interposed therebetween in the circumferential direction of the main body 60, and emit light downward. When imaging is performed by the first camera 61, light is emitted from each illumination part 65 to a subject below. The first camera 61, the second camera 62, and the mirror 64 may be provided closer to the center of the main body 60 than the solvent supply nozzle 51B so as not to interfere with the solvent supply nozzle 51B when imaging the solvent supply nozzle 51B at the processing position while rotating the inspection wafer 6, as will be described later.

A device mounting board 71 is provided in the central portion of the main body 60. The above-described boards 67A and 67B are connected to the device mounting board 71 via cables (not illustrated), and the image data acquired by the first camera 61 and the second camera 62 is transmitted to the device mounting board 71 via the boards 67A and 67B and the cable. The device mounting board 71 includes plural boards including, for example, a digital signal processor (DSP) board, but is illustrated as a single board for convenience, and various devices are mounted thereon. These devices include a device that performs imaging by the first camera 61 and the second camera 62 by wirelessly receiving a signal from the arithmetic device 8, a device that switches turning-on/off of light emission by the illumination part 68, a device (transmitter) that wirelessly transmits the acquired image data to the arithmetic device 8, and the like. A battery 72 is provided in the central portion of the main body 60 to supply power to the first camera 61, the second camera 62, each device included in the device mounting board 71, and the illumination part 68.

Subsequently, the arithmetic device 8 will be described with reference to FIG. 5. The arithmetic device 8 is a computer and includes a bus 81. A program storage part 82, a wireless transmission/reception part 83, a memory 84, a display part 85, and an operation part 86 are each connected to the bus 81. A program 80 stored in a storage medium such as a compact disk, a hard disk, a memory card, or a DVD is installed in the program storage part 82.

The wireless transmission/reception part 83 is a device for wirelessly transmitting a signal that becomes a trigger for acquiring image data of the inspection wafer 6 and wirelessly receiving each acquired image data. The acquired image data and pre-preparation data, which will be described in detail later, are stored in the memory 84, which corresponds to first and second storage parts. The display part 85 is a display, and displays each of the acquired cup separation distance H0 and nozzle separation distance H1. The operation part 86 is configured with a mouse, a keyboard, or the like, and the user of the information acquisition system 1 may instruct the execution of processing that can be performed by the program 80, such as transmission of the above-described trigger signal, via the operation part 86.

In addition, for example, the arithmetic device 8 is connected to the controller 20 of the substrate processing apparatus 2 and is able to transmit and receive data or signals necessary for acquiring the cup separation distance H0 and the nozzle separation distance H1. For example, when the inspection wafer 6 is placed on the spin chuck 31, a signal indicating that image data can be acquired is transmitted from the controller 20 to the arithmetic device 8.

The above-described program 80 of the arithmetic device 8 is supplementarily described. A group of steps is set in the program 80 to be capable of performing transmission/reception of each data and signal described above, storage of image data in the memory 84, acquisition of the cup separation distance H0 and the nozzle separation distance H1 based on the image data and the pre-preparation data, display of the acquired cup separation distance H0 and nozzle separation distance H1 on the display part 85, and the like. Therefore, the program 80 constitutes an acquisition part that acquires the distance (height) between the wafer W and an imaged object to be imaged by the camera. The program 80 also specifies predetermined pixels in the image data for acquiring the cup separation distance H0 and the nozzle separation distance H1, which will be described later, detects the number of pixels in a predetermined region, and performs various arithmetic operations.

Subsequently, the pre-preparation data stored in the memory 84 of the arithmetic device 8 as described above will be described, and the method of acquiring the cup separation distance H0 and the nozzle separation distance H1 from the pre-preparation data will be described. The pre-preparation data includes data for acquiring the cup separation distance H0 and data for acquiring the nozzle separation distance H1. First, the data for acquiring the cup separation distance H0 will be described with reference to FIG. 8.

Outside the substrate processing apparatus 2, the jig 91 is disposed below the inspection wafer 6 in a region where it can be imaged by the first camera 61. The shape of the jig 91 is not limited, but the jig 91 is, for example, a member that is elongated and extends in the lateral direction (front/rear direction of the paper surface of FIG. 8) like the annular protrusion 47. The width L1 of the upper end surface of the jig 91 is known and is, for example, 1 mm. It is assumed that the separation distance between the jig 91 and the bottom surface of the main body 60 of the inspection wafer 6 is H2 (unit: mm). The separation distance H2 is changed, and the jig 91 is imaged and image data is acquired each time the distance is changed. That is, plural image data about the jig 91 are acquired.

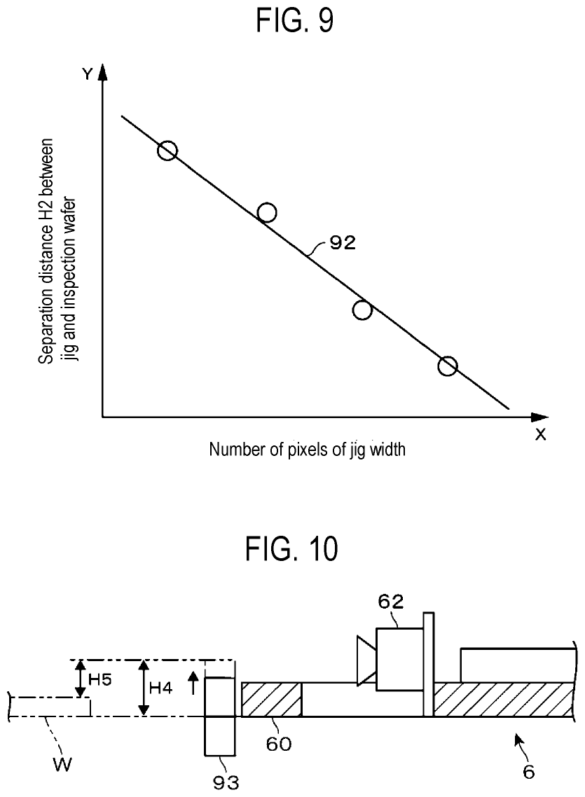

Then, the number of pixels of the width of the upper end surface of the jig 91 in each image data is acquired, and the correspondence between the number of pixels and the separation distance H2 is obtained from the acquisition result as illustrated in a graph of FIG. 9. In this graph, the number of pixels on the upper end surface of the jig 91 is set on the X axis, and the separation distance H2 is set on the Y axis, and each point in the graph is an acquisition result. Then, for example, Y=AX+B (A and B are constants), which is an approximate expression of a linear function, is obtained from each of the points. As described above, the approximate expression represents the amount of change in the number of pixels on the upper end surface of the jig 91 with respect to the amount of change in the separation distance H2, and is shown as a straight line 92 in the drawing. In addition, the width L2 of the upper end portion of the annular protrusion 47 (see FIG. 4) is acquired. The above-described approximate expression Y=AX+B and the width L2 are pre-preparation data for acquiring the cup separation distance H0.

The procedure for acquiring the cup separation distance H0 from the above-described pre-preparation data will be described. When the image data of the annular protrusion 47 illustrated in FIG. 7 is acquired by the first camera 61 in the state in which the inspection wafer 6 is held by the spin chuck 31 as illustrated in FIGS. 5 and 6, the pixels at one end and the other end of the width L3 of the annular protrusion 47 in the image data are specified. Then, the number of pixels from the pixels at the one end to the pixels at the other end is detected. That is, the number of pixels of the width L3 of the annular protrusion 47 in the image data is detected (step S1). In the example of the image illustrated in FIG. 7, the number of pixels is 14. Then, in the above-described approximate expression Y=AX+B, the value of Y in the approximate expression is calculated by using the number of pixels of the width L3 as the value of X (step S2).

As described above, since this approximate expression is obtained by using the jig 91 having a width L1 of 1 mm, the value of Y calculated as described above corresponds to the separation distance H2 between the annular protrusion 47 and the inspection wafer 6 in the case in which the width L2 of the annular protrusion 47 is 1 mm. Both the bottom surface of the wafer W and the bottom surface of the main body 60 of the inspection wafer 6 are flat, and the bottom surface of the main body 60 and the bottom surface of the wafer W have the same height when held by the spin chuck 31. Therefore, the value of Y is also the distance (=cup separation distance H0) between the annular protrusion 47 and the bottom surface of the wafer W when the width L2 is 1 mm. Therefore, by multiplying Y by the width L2 of the annular protrusion 47, correction is made to correspond to the actual width L2 of the annular protrusion 47, and this multiplication value (=Y×L2) is determined as the cup separation distance H0 (step S3). The cup separation distance H0 calculated in this way is displayed on the display part 85 of the arithmetic device 8 (step S4). The foregoing steps S1 to S4 are performed by the above-described program 80. Further, the above-described approximate expression Y=AX+B is correlation data representing the correlation between the number of pixels of the width of the annular protrusion 47 when the width of the annular protrusion 47 is 1 mm and the distance between the wafer W and the annular protrusion 47. Then, L2 multiplied by Y as described above corresponds to the correction data for correcting this correlation data.

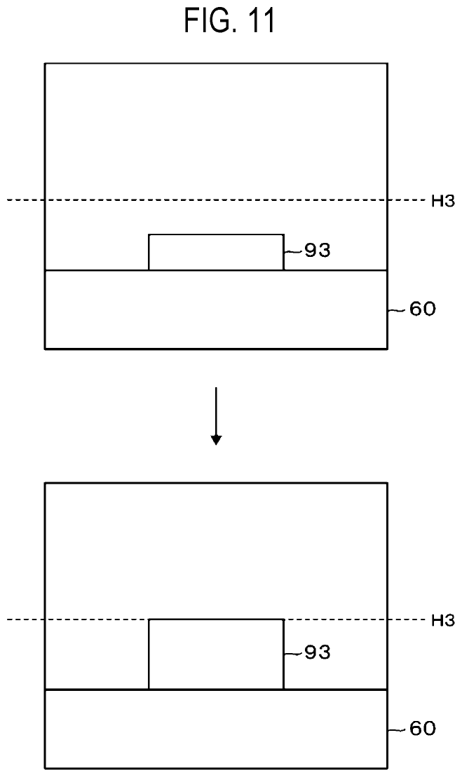

Subsequently, the pre-preparation data for acquiring the nozzle separation distance H1 will be described with reference to FIGS. 10 and 11. An image acquired by the second camera 62 will be described as a VGA image, that is, an image having 640 pixels in the horizontal direction and 480 pixels in the vertical direction. As illustrated in FIG. 10, the jig 93 is disposed close to the lateral side of the inspection wafer 6, and the jig 93 is imaged by the second camera 62 to acquire image data. The shape of the jig 93 is not limited, but is, for example, a rod-shaped member extending in the vertical direction. The relative height between the jig 93 and the inspection wafer 6 is changed such that the upper end of the jig 93 appears in the pixels positioned at the reference height H3 which is the center of the image in the vertical direction, that is, the 240 pixels counting from the lower end of the image. That is, the upper end of the jig 93 is aligned with the reference height. FIG. 11 schematically illustrates an image acquired by the second camera 62 in changing the relative height in that way. In the example illustrated in FIG. 10, the jig 93 is raised with respect to the inspection wafer 6, and when the jig 93 is positioned at the position indicated by the alternate long and short dash line in FIG. 10, the upper end of the jig 93 is illustrated as being positioned at the reference height H3 in the image as illustrated in the lower portion of FIG. 11.

When the upper end of the jig 93 is positioned at the reference height H3, the height H4 between the upper end of the jig 93 and the bottom surface of the inspection wafer 6 is acquired. The method of acquiring the height H4, which is the fourth distance, is arbitrary, but by using a jig such as a caliper, the distance between the upper end of the jig 93 and a height position which is the same as the bottom surface of the inspection wafer 6 in the jig 93 may be measured. In the above-described example, the upper end of the jig 93 is aligned with the reference height H3. However, the height H4 may be obtained by indicating a mark on the side surface of the jig 93, aligning this mark with the reference height H3, and measuring the distance between the mark and the bottom surface of the inspection wafer 6. In this way, the height H4 may be obtained by aligning an arbitrary position on the jig 93 with the reference height H3.

A height H5 is obtained by subtracting the thickness of the wafer W from the height H4 obtained as described above. As described above, the heights of the bottom surface of the wafer W placed on the spin chuck 31 and the bottom surface of the inspection wafer 6 placed on the spin chuck 31 are the same. Therefore, this height H5 is a difference in height between the front surface of the wafer W placed on the spin chuck 31 and an actual height position corresponding to the height appearing as the reference height H3 in the image acquired by the second camera 62 of the inspection wafer 6 placed on the spin chuck 31 (see FIG. 10). This H5, which is the third distance, is set as a wafer reference height. In addition, the width L4 of the solvent supply nozzle 51B (see FIG. 4) is acquired. This width L4 is conversion information used for converting the number of pixels of image data into an actual distance, as will be described later. The wafer reference height H5 and the width L4 of the solvent supply nozzle 51B are pre-preparation data for acquiring the nozzle separation distance H1.

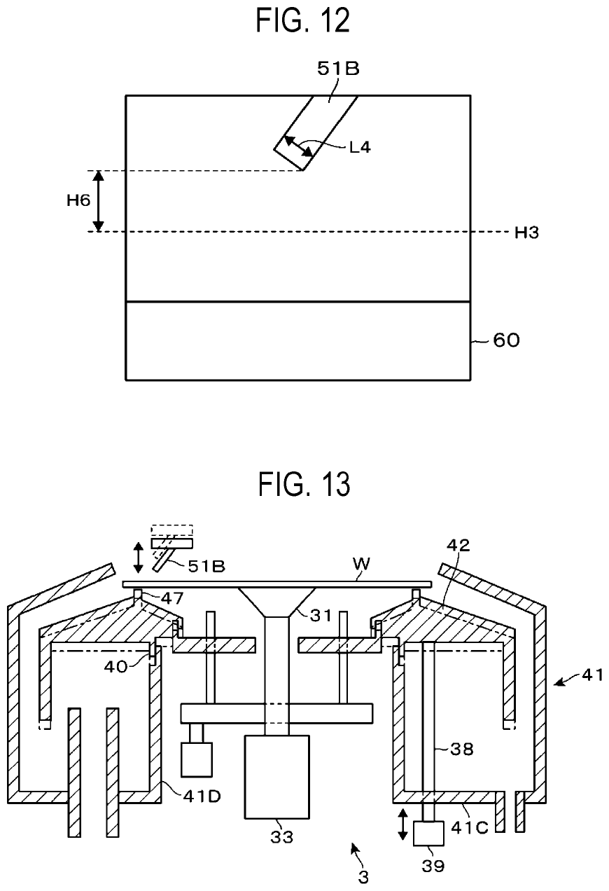

The procedure for acquiring the nozzle separation distance H1 from the above-described pre-preparation data will be described. In the state in which the inspection wafer 6 is held by the spin chuck 31 as illustrated in FIGS. 5 and 6, image data of the side surface of the solvent supply nozzle 51B is acquired by the second camera 62 as illustrated in FIG. 12. In this image data, the lower end of the solvent supply nozzle 51B is specified. In addition, in the image data, the number of pixels corresponding to the width L4 of the solvent supply nozzle 51B is detected (step T1). Specifically, in the detection of the number of pixels corresponding to the width L4, each of a pixel of one end (referred to as a “first pixel”) and a pixel of the other end (referred to as a “second pixel”) in the width direction of the solvent supply nozzle 51B is specified, and the number of pixels between the first pixel and the second pixel is detected. Specifically, assuming that the first pixel and the second pixel are separated by, for example, 3 pixels in the vertical direction and 4 pixels in the horizontal direction, the number of pixels corresponding to the width L4 is (3²+4²)^{1/2} 5 pixels.

Subsequently, in the image data, the number of pixels in the height H6 between the lower end of the solvent supply nozzle 51B specified in step T1 and the reference height H3 (that is, pixels having a preset height in the image data) is detected (step T2). The H6 is set as a nozzle reference height. Then, the width L4 of the solvent supply nozzle 51B which is the pre-preparation data/the number of pixels corresponding to the width L4 acquired in step T1 is calculated, and this calculated value is taken as the distance in one pixel (step T3). Then, the number of pixels of the nozzle reference height H6 obtained in step T2×the distance in one pixel obtained in step T3 is calculated. That is, the nozzle reference height H6, which is the number of pixels on the image data, is converted into an actual height (distance) (step T4).

Then, when the lower end of the solvent supply nozzle 51B is positioned below the reference height H3 in the image data, the wafer reference height H5 which is the pre-preparation data minus the actual nozzle reference height H6 obtained in step T4 is calculated. In addition, as illustrated in FIG. 12, when the lower end of the solvent supply nozzle 51B is positioned above the reference height H3 in the image data, the wafer reference height H5 which is pre-preparation data plus the actual nozzle reference height H6 obtained in step T4 is calculated.

The calculated value acquired by subtracting H6 from H5 or adding H6 to H5 is determined as the nozzle separation distance H1 (step T5), and is displayed on the display part 85 of the arithmetic device 8 (step T6). The foregoing steps T1 to T6 are performed by the above program 80.

As described above, the height between the front surface of the wafer W and the reference height H3 of the image is set as H5 and acquired as pre-preparation data. Then, by imaging the solvent supply nozzle 51B, the height between the lower end of the nozzle 51 and the reference height H3 of the image is acquired as H6, and H6 is added or subtracted with respect to H5. That is, the nozzle separation distance H1 between the front surface of the wafer W and the lower end of the solvent supply nozzle 51B is calculated stepwise by dividing the nozzle separation distance H1 with reference to the reference height H3. The nozzle separation distance H1 is calculated in this way because the field of view of the second camera 62 is limited.

The reason for calculating the nozzle separation distance H1 as described above will be described in detail below. It is assumed that the second camera 62 is able to image the solvent supply nozzle 51B and a position directly below the solvent supply nozzle 51B in the main body 60 of the inspection wafer 6. In that case, the nozzle separation distance H1 may be calculated by obtaining the height between the main body 60 and the solvent supply nozzle 51B from the number of pixels between the solvent supply nozzle 51B and the position directly below the same and the distance in one pixel obtained in the above-described step T3 above, and adding the thickness difference between the wafer W and the main body 60.

However, since the inspection wafer 6 is transported by the transport mechanisms 23 and 25, the second camera 62 is arranged on the main body 60 of the inspection wafer 6 as described above. Due to such a restriction on the arrangement, the field of view of the second camera 62 is limited, and thus the position directly below the solvent supply nozzle 51B in the main body 60 may not be imaged. Therefore, as described above, the nozzle separation distance H1 is calculated stepwise by dividing the nozzle separation H1 into heights H5 and H6 with reference to the reference height H3. Therefore, according to this method, there is an effect in that it is possible to calculate the nozzle separation distance H1 with high accuracy while enabling the inspection wafer 6 to be transported by the transport mechanisms 23 and 25. Although the center of the image in the vertical direction is set as the reference height H3, any height may be set as the reference height without being limited to the center. For example, the height from the lower end of the image to 1/4 of the entire image (i.e., 120 pixels from the lower end) may be set as the reference height. Although the number of pixels for the width L4 of the solvent supply nozzle is acquired in step T1, the number of pixels is not limited to being acquired each time the nozzle separation distance H1 is calculated, and may be stored in the memory 84 of the arithmetic device 8 as, for example, a fixed value.

The operation procedure of the information acquisition system 1 described above will be described. First, as preparation processes, the jigs 91 and 93 described in FIGS. 8 and 10 are imaged, and the approximate expression and the wafer reference height H5 described with reference to FIG. 9 are acquired. In addition to the approximate expression and the wafer reference height H5, the width L2 of the annular protrusion 47 and the width L4 of the solvent supply nozzle 51B are stored in the memory 84 of the arithmetic device 8 as pre-preparation data.

After the completion of the above-described preparation processes, the carrier C in which the inspection wafer 6 is stored is transported to the stage 21 of the substrate processing apparatus 2. The inspection wafer 6 is transported in the order of the transport mechanism 23, the delivery module TRS, the transport mechanism 25, and the resist film forming module 3, and is placed on a spin chuck 31 via the lifting pins 35 to be attracted and held. Thereafter, the solvent supply nozzle 51B moves from the standby part 55B to the processing position.

When a user gives a predetermined instruction from the arithmetic device 8, the spin chuck 31 rotates intermittently, for example, in increments of a predetermined angle, and when the rotation is stopped, imaging is performed by the second camera 62 and image data is acquired. The acquired image data is sequentially transmitted wirelessly to the arithmetic device 8. When the image data of the entire circumference on the peripheral edge of the inspection wafer 6 is acquired, the intermittent rotation and the imaging of the second camera 62 are stopped, and the solvent supply nozzle 51B returns to the standby part 55B. Then, the top surface of the annular protrusion 47 is imaged by the first camera 61, and the image data illustrated in FIG. 7 is wirelessly transmitted to the arithmetic device 8.

The foregoing steps S1 to S4 are executed for the image data acquired by the first camera 61, the cup separation distance H0 is calculated, and the cup separation distance H0 is screen-displayed on the display part 85 of the arithmetic device 8. In addition, from among plural image data acquired by the second camera 62, for example, image data in which the solvent supply nozzle 51B is captured as illustrated in FIG. 12 is selected by the program 80 of the arithmetic device 8. Then, the foregoing steps T1 to T6 are executed for the selected image data, the nozzle separation distance H1 is calculated, and the nozzle separation distance H1 is screen-displayed on the display part 85 of the arithmetic device 8.

The inspection wafer 6 for which imaging has been completed is delivered to the transport mechanism 25 via the lifting pins 35, is carried into another resist film forming module 3, and is imaged in the same manner as when the inspection wafer was carried into the previous resist film forming module 3. As a result, the cup separation distance H0 and the nozzle separation distance H1 are also calculated for the resist film forming module 3 and screen-displayed. When the cup separation distance H0 and the nozzle separation distance H1 are acquired for all the resist film forming modules 3, the inspection wafer 6 is returned to the carrier C via the transport mechanism 25, the delivery module TRS, and the transport mechanism 23 in this order. The operator sees the cup separation distance H0 and the nozzle separation distance H1 screen-displayed for each resist film forming module 3, and performs height adjustment for the guide part 42 of the cup 4 including the annular protrusion 47 or the solvent supply nozzle 51B in the resist film forming module 3 which is determined to require adjustment.

Thereafter, the carrier C in which the wafer W is stored is transported to the stage 21 of the substrate processing apparatus 2. The wafer W is transported in the order of the transport mechanism 23, the transport module TRS, the transport mechanism 25, the resist film forming module 3, the transport mechanism 25, the heating module 26, the transport mechanism 25, and the delivery module TRS, and is returned to the carrier C by the transport mechanism 23. In the resist film forming module 3, a resist is ejected from the resist supply nozzle 51A to the center portion of the front surface of the wafer W rotated by the spin chuck 31, the resist spreads toward the peripheral edge of the wafer W, and a resist film is formed on the entire front surface of the wafer W. Thereafter, the solvent supply nozzle 51B moves from the standby part 55B to the processing position, and the solvent is supplied to the peripheral edge of the rotating wafer W to remove the resist film on the peripheral edge.

As described above, according to the information acquisition system 1, the cup separation distance H0 and the nozzle separation distance H1 are acquired, and the operator may adjust the resist film forming module 3 based thereon. Therefore, the resist film forming module 3 is prevented from becoming defective in wafer W processing. As a result, it is possible to prevent a decrease in the yield of semiconductor products manufactured from the wafer W. In the above-described system operation procedure, preparation processes are performed before the acquisition of the image data to acquire pre-preparation data, but the preparation processes may be performed after the image data is acquired.

FIG. 13 illustrates another configuration example of the cup 4. In the cup 4, the upper end of a support column 38 is connected to the lower portion of the guide part 42 including the annular protrusion 47. The lower end of the support column 38 penetrates the bottom main body 41C of the cup main body 41 and is connected to the lifting mechanism 39 which is the first lifting mechanism, and the guide part 42 is movable upward and downward by this lifting mechanism 39. Even if the guide part 42 moves upward and downward in this way, no gap is formed between the inner cylindrical portion 41D of the cup main body 41 and the guide part 42 due to the lower annular protrusion 40 of the guide part 42, and the processing liquid or mists thereof inside the cup 4 do not leak to the outside of the cup 4.

When the acquired cup separation distance H0 is out of a permissible range, for example, a control signal is output by the controller 20, and the height of the guide part 42 is adjusted by the lifting mechanism 39 to fall within the permissible range. That is, the relative height between the spin chuck 31 and the annular protrusion 47 is changed depending on the cup separation distance H0.

In addition, when the acquired nozzle separation distance H1 is out of the permissible range, for example, a control signal is output by the controller 20, and the height of the solvent supply nozzle 51B at the processing position may be adjusted to fall within the permissible range by the moving mechanism 54B (see FIG. 13). That is, the moving mechanism 54B is the second lifting mechanism, and the relative height between the solvent supply nozzle 51B and the spin chuck 31 is changed depending on the nozzle separation distance H1. In addition, in order to make each of the cup separation distance H0 and the nozzle separation distance H1 capable of falling within the permissible range, the lifting mechanism 39 and the moving mechanism 54B are configured to change each of the height of the guide part 42 and the height of the solvent supply nozzle 51B in multiple steps.

With the configuration in which the cup separation distance H0 and the nozzle separation distance H1 are automatically adjusted in this way, the operator's labor of adjusting the heights of the guide part 42 and the solvent supply nozzle 51B is eliminated. In addition, since the processing of the wafer W in the substrate processing apparatus 2 is prevented from being stopped for performing the height adjustment, it is possible to increase the productivity of the substrate processing apparatus 2. In the case of the configuration in which the cup separation distance H0 and the nozzle separation distance H1 are automatically adjusted in this way, the cup separation distance H0 and the nozzle separation distance H1 may not be displayed on the display part 85. Therefore, the system configuration may not be provided with the display part 85. In addition, the system may have a configuration in which the cup separation distance H0 and the nozzle separation distance H1 are adjustable by connecting the rotation mechanism 33, which is connected to the spin chuck 31, to the lifting mechanism and moving the spin chuck 31 and the rotation mechanism 33 upward and downward with respect to the cup 4 and the solvent supply nozzle 51B.

For convenience of explanation, the cup 4 of one resist film forming module 3 in the substrate processing apparatus 2 is denoted by 4A, and the cup 4 of the other resist film forming module 3 is denoted by 4B. It is assumed that the widths L2 of the top surfaces of the annular protrusions 47 of respective cups 4A and 4B are different from each other. In that case, the width L2 of the cup 4A and the width L2 of the cup 4B may be stored in the memory 84 of the arithmetic device 8 as the pre-preparation data, and calculation may be performed by using the width L2 according to the cup 4 for which the cup separation distance H0 is acquired. That is, the width L2 which is the pre-preparation data may be stored for each cup 4 and selected according to a cup 4 for which the cup separation distance H0 is acquired, so that the above-described calculation can be performed.

The operator may select the width L2, which is the corrected data used for this calculation, from the arithmetic device 8. Alternatively, for example, the correspondence between the resist film forming module 3 and the width L2 in the module is stored in the memory 84 of the arithmetic device 8. Then, when the inspection wafer 6 is transported to one of the resist film forming modules 3, information about the resist film forming module 3 may be transmitted from the controller 20 of the substrate processing apparatus 2 to the arithmetic device 8, the program 80 of the arithmetic device 8 may select the width L2 corresponding to the resist film forming module 3 according to the information, and the cup separation distance H0 may be calculated. That is, depending on a resist film forming module 3 to which the inspection wafer 6 is transported, the width L2 of the cup 4 of the resist film forming module 3 may be automatically selected.

In the above-described example, only one location in the circumferential direction is imaged for the annular protrusion 47 to calculate the cup separation distance H0, but plural locations in the circumferential direction may be imaged by the first camera 61, and each cup separation distance H0 may be acquired from each image data. By acquiring the cup separation distances H0 at a plurality of locations in this way, it is possible to detect an abnormality in which the guide part 42 is installed to be inclined. That is, when some locations in the circumferential direction of the annular protrusion 47 fall within the permissible range but the other locations do not fall within the permissible range, it may be detected as abnormal. When imaging by the first camera 61 is performed plural times as described above, the imaging may be performed together with, for example, imaging by the second camera 62. That is, when the inspection wafer 6 is intermittently rotated and the second camera 62 performs imaging when the rotation is stopped, imaging by the first camera 61 may also be performed.

In the information acquisition system 1 described above, the controller 20 and the arithmetic device 8 are separately provided, but the controller 20 may be configured to also serve as the arithmetic device 8. In addition, although the image data is wirelessly transmitted to the arithmetic device 8 in the above-described example, for example, a detachable memory may be mounted on the main body of the inspection wafer 6, and the image data may be stored in the memory. In that case, the operator may remove the memory from the inspection wafer 6 returned to the carrier C after completing imaging and transfer the image data to the arithmetic device 8 so that the cup separation distance H0 and the nozzle separation distance H1 can be acquired. Therefore, the inspection wafer 6 does not have to be configured to wirelessly transmit image data. The inspection wafer 6 and the arithmetic device 8 may be connected by wire, and the image data may be transmitted to the arithmetic device 8. However, since there is a possibility that the transport of the inspection wafer 6 may be hindered by members such as interconnection cables, the configuration in which image data is wirelessly transmitted as described above or stored in a memory mounted on the inspection wafer 6 is more advantageous.

In addition, the inspection wafer 6 may have a configuration in which only one of the first camera 61 and the second camera 62 is mounted on the main body 60, and image data is acquired by using only one of the annular protrusion 47 and the solvent supply nozzle 51B as an object to be imaged, and only one of the cup separation distance H0 and the nozzle separation distance H1 is acquired. The object to be imaged by the first camera 61 is not limited to the annular protrusion 47. For example, it is assumed that the top surface of the guide part 42 is a flat surface, and a nozzle is provided as an upward protrusion on the flat surface. This nozzle ejects the cleaning liquid toward the peripheral edge of the bottom surface of the wafer W. The nozzle may be imaged by the first camera 61, and the separation distance between the nozzle and the bottom surface of the wafer W may be acquired by the method described above. The processing liquid supplied from the nozzle to the peripheral edge of the wafer W is not limited to the solvent, and may be, for example, a coating liquid for forming a coating film. The heights of the nozzle and the front surface of the wafer W may be calculated by the method described above.

The arrangement of the second camera 62 of the inspection wafer 6 is supplementarily described. Generally, distortion occurs in an image acquired by a camera, and the distortion on the peripheral edge side is larger than that on the center side. Therefore, in an image acquired by the second camera 62, when the lower end of the solvent supply nozzle 51B is positioned at the upper end or the lower end of the image, there is a possibility that an error may occur in the calculated nozzle separation distance H1 relative to the actual distance. In order to suppress the error, the second camera 62 is provided on the main body 60 of the inspection wafer 6 such that, regarding the solvent supply nozzle 51B that has been moved to the above-described processing position, which is a preset position, when the processing position is normal, the lower end of the solvent supply nozzle 51B is positioned in the height center portion of the image. Therefore, when the solvent supply nozzle 51B is in the normal height position in the image illustrated in FIG. 12, the upper end of the arrow H6 is positioned in the height center portion of the image. Assuming that the height of an acquired image is X pixels, the height center portion of the image is, for example, a height shifted upward by X/10 pixels with respect to the height center of the image to a height shifted by X/10 pixels downward with respect to the image.

In order to capture the solvent supply nozzle 51B in the image in this way, the second camera 62 may be provided such that the lower portion thereof enters the through hole 66B formed in the main body 60 as illustrated in FIG. 5, or a stand may be provided on the main body 60, and the second camera 62 may be installed on the stand. That is, like the through hole and the stand, a height changing part for changing the heights of the front surface (top surface) of the main body 60 and the lower end of the second camera 62 may be provided. In addition, in order to facilitate height adjustment of the solvent supply nozzle 51B in the image in that way, the second camera 62 may be configured to be adjustable in height in the main body 60. As a specific example, in the above-described example, the second camera 62 is provided on the board 67B oriented in the vertical direction, but a bar screw protrudes on the main body 60, a nut is screw-coupled to the main body 60, and the board 67B is horizontally provided on the nut. The second camera 62 is disposed on the board 67B, and the operator turns the nut to change the height of the board 67B so that the height of the second camera 62 is changed together with the board 67B.

Alternatively, the board 67B may be connected to the main body 60 via a slide rail extending in the vertical direction so that the height of the board 67B with respect to the main body 60 can be adjusted by the operator. Like the bar screw, the nut, and the slide rail, a height changing part for changing the height of the second camera 62 with respect to the main body 60 may be provided. Regarding the image acquired by the second camera 62, when the lower end of the solvent supply nozzle 51B is not positioned in the height center portion of the image as described above, it may be determined that the height of the solvent supply nozzle 51B is abnormal without acquiring the nozzle separation distance H1.

The second camera 62 is provided to image the solvent supply nozzle 51B, but may be provided to be able to image the resist supply nozzle 51A such that the distance between the resist supply nozzle 51A and the front surface of the wafer W may be acquired. In addition, the liquid processing module provided in the substrate processing apparatus 2 is not limited to the resist film forming module 3. The liquid processing module may be a film forming module that supplies a processing liquid for forming a coating film other than a resist film, such as an antireflection film or an insulating film, to a front surface of a wafer W from a nozzle or a module that supplies, to a front surface of a wafer, a cleaning liquid, a developing liquid, or an adhesive for bonding plural wafers W from a nozzle. The distance between the nozzle that supplies a processing liquid other than a resist and the front surface of the wafer W in that way may also be acquired by the present technology. The inspection wafer 6 is not limited to being transported from the outside to the substrate processing apparatus 2 by the carrier C. For example, a module for storing the inspection wafer 6 may be provided in the substrate processing apparatus 2 so that the inspection wafer 6 is transported between the module and the resist film forming module 3.

### Second Embodiment

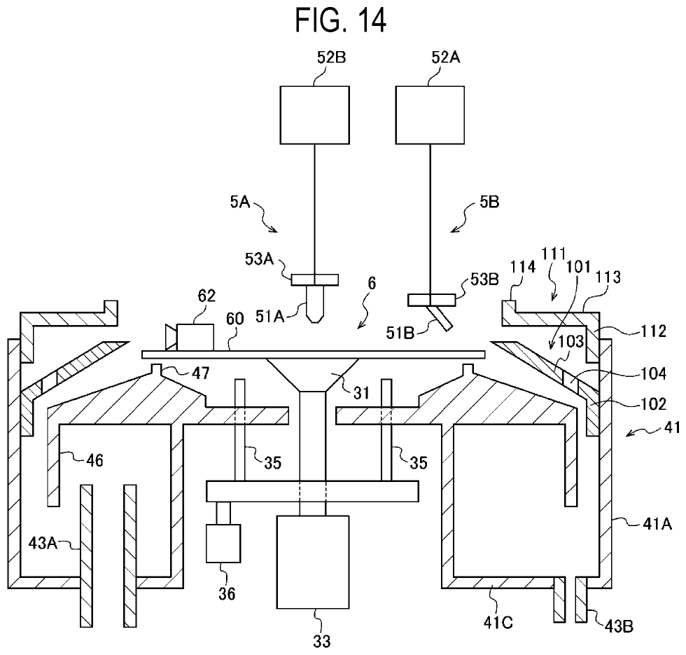

Next, an inspection example of a second embodiment using the inspection wafer 6 will be described. Therefore, first, the configuration of the cup 4 of the resist film forming module 3 will be described in more detail with reference to a vertical cross-sectional side view of FIG. 14. The cup 4 includes an intermediate guide part 101 and an upper guide part 111. Further, FIG. 2 illustrates the intermediate guide part 101 as the inclined portion 41B in a simplified form, and the upper guide part 111 is omitted in FIG. 2.

The intermediate guide part 101 includes a vertical wall 102 installed on the inner peripheral surface of the outer cylindrical portion 41A constituting the cup 4, and an inclined wall 103 extending obliquely upward from the upper end of the vertical wall 102 toward the center side of the cup 4. The inclined wall 103 is formed in an annular shape in a plan view. A through hole 104 for discharging liquid is perforated in the inclined wall 103 in the vertical direction.

The upper guide part 111 includes an upper vertical wall 112 installed on the inner peripheral surface of the outer cylindrical portion 41A, an upper wall 113 extending substantially horizontally from the upper end of the upper vertical wall 112 toward the center side of the cup 4, and a cylindrical opening wall 114 extending vertically upward from the tip end of the upper wall 113. The upper vertical wall 112 is provided above the vertical wall 102 of the intermediate guide part 101, and the upper wall 113 is positioned above the inclined wall 103 of the intermediate guide part 101.

Due to the above-described configuration, the side wall of the cup 4 is configured with the outer cylindrical portion 41A, and the vertical wall 102 of the intermediate guide part 101, and the upper vertical wall 112. The inclined wall 103 protrudes from a position lower than the upper end of the side wall, and the upper wall 113 protrudes from the upper end of the side wall toward the center of the cup 4. The inclined wall 103 and the upper wall 113 form an annular protrusion body protruding from the side wall in this way, and form an annular ring surrounding the wafer W placed on the spin chuck 31 coaxially with the central axis of the spin chuck 31 in a plan view.

The upper guide part 111, which is an upper annular body, and the intermediate guide part 101, which is an intermediate annular body, may be installed in the outer cylindrical portion 41A of the cup 4 in the state of becoming abnormal in height due to an error during assembly or adjustment of the cup 4. This height abnormality also includes the case in which the cup main body 41 is obliquely installed and the height of only a portion in the circumferential direction becomes abnormal. In such a state in which the height is abnormal, since desired exhaust performance is not obtained in each portion inside the cup 4, the processing of a wafer W may become poor, or the mists of the processing liquid may scatter to the outside of the cup 4. In addition, in the case in which the height of the upper guide part 111 is abnormal, the upper guide part 111 may interfere with each nozzle passing over the cup 4.

In the second embodiment, by using the image data acquired by the second camera 62 in the inspection wafer 6, information about each of the heights of the solvent supply nozzle 51B, the intermediate guide part 101, and the upper guide part 111 is acquired. More specifically, the second camera 62 is arranged to be capable of imaging not only the side surface of the solvent supply nozzle 51B, but also the inner peripheral end of the intermediate guide part 101 (i.e., the inner peripheral end of the inclined wall 103) and the inner peripheral end of the upper guide part 111 (i.e., the inner peripheral end of the opening wall 114). In addition, from the information of each height, it is determined whether or not there is an abnormality in the solvent supply nozzle 51B, the intermediate guide part 101, and the upper guide part 111. As a result, processing a wafer W while an abnormality occurs is prevented, and a decrease in yield is prevented. In each drawing illustrating the second embodiment, among the members mounted on the main body 60 of the inspection wafer 6, illustration of each of the above-described members other than the second camera 62 is omitted.

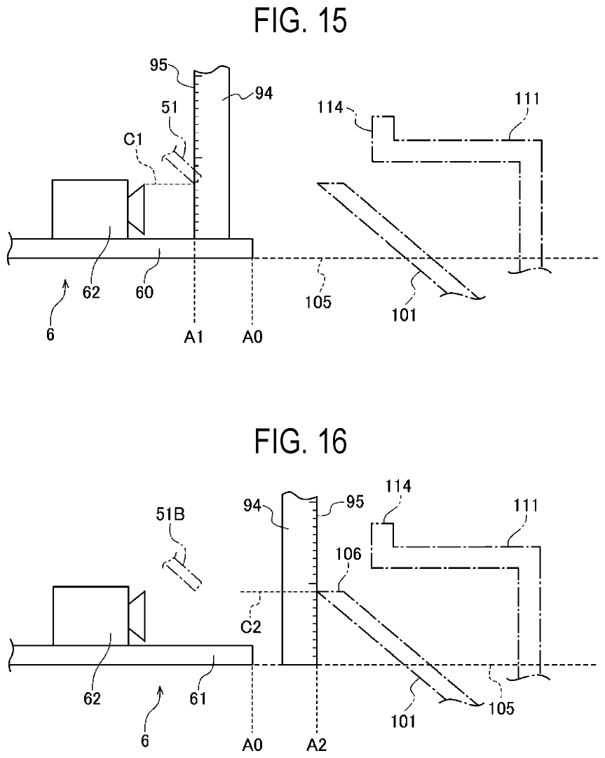

Pre-preparation for performing the above-described inspection (abnormality determination) will be described with reference to FIGS. 15 to 17. As this pre-preparation which is a calibration work, setting of a reference height in an image acquired by the second camera 62 and acquisition of a pixel pitch in the vertical direction of the image are individually performed for the solvent supply nozzle 51B, the intermediate guide part 101, and the upper guide part 111, which are abnormality detection targets. The pixel pitch is the correspondence between the number of pixels and an actual distance, and more specifically, an actual distance per pixel. For this pre-preparation, for example, a scale 94 is used as a jig. For this scale 94, the linear edge on the side where gradations are provided is denoted by 95.

As described above, the diameter of the main body 60 of the inspection wafer 6 is the same as the diameter of the wafer W. An arbitrary position at the peripheral end of the main body 60 is set as a reference position A0. As will be described later, this reference position A0 is a position at which, when performing the imaging by shifting the scale 94 in the radial direction of the main body 60 with respect to the reference position A0, the imaging can be performed, for example, a point that overlaps the optical axis of the second camera 62 in a plan view.

FIG. 15 illustrates a state of pre-preparation for inspecting the solvent supply nozzle 51B. Assuming that the lower end of the solvent supply nozzle 51B at the processing position is disposed at a position separated away from the reference position A0 by A1 mm toward the center of the wafer W along the radial direction of the wafer W, first, the operator places the main body 60 of the inspection wafer 6 on an arbitrary horizontal plane 105. Then, the scale 94 is vertically disposed on the front surface of the main body 60 at the position separated away from the reference position A0 by A1 mm along the radial direction of the main body 60. More specifically, respective gradations of the scale 94 are arranged in the vertical direction, and the scale 94 is disposed such that the edge 95 of the scale 94 extends in the vertical direction at the position separated away from the reference position A0 by A1 mm in the radial direction of the main body 60. The scale 94 disposed in that way is imaged by the second camera 62 to acquire image data.

Subsequently, the operator determines the pixel at the height indicated by a specific gradation of the scale 94 in the image data as a reference height pixel B1. The height indicated by the specific gradation is a gradation that is the height of the lower end of the solvent supply nozzle 51B when the solvent supply nozzle 51B is normally disposed at the processing position, and is set as a reference height C1. In addition, a pixel pitch (referred to as “pixel pitch 1”) is acquired from the number of pixels between adjacent gradations on the scale 94 in the image data.

The pre-preparation for performing inspection of the intermediate guide part 101 and the upper guide part 111 is the same as the pre-preparation for the solvent supply nozzle 51B, except that the scale 94 is disposed differently. The pre-preparation for the intermediate guide part 101 will be specifically described with reference to FIG. 16, focusing on the differences from the pre-preparation for the solvent supply nozzle 51B. It is assumed that, when the cup 4 is normally assembled with respect to the intermediate guide part 101, the upper end of the intermediate guide part 101 is disposed at a position separated away from the reference position A0 by A2 mm to the outside of the wafer W along the radial direction of the wafer W. In that case, the operator disposes the scale 94 at the position separated away from the reference position A0 by A2 mm such that the edge 95 extends in the vertical direction. Then, the operator acquires the image data of the scale 94 by the second camera 62. In this image data, a gradation indicating the height of the upper end of the intermediate guide part 101 (referred to as “reference height C2”) when the assembly of the cup 4 is normal is detected, and the pixel at the height at which the gradation is captured is determined as a reference height pixel B2. In addition, a pixel pitch (pixel pitch 2) is acquired from the scale 94 in the image data.

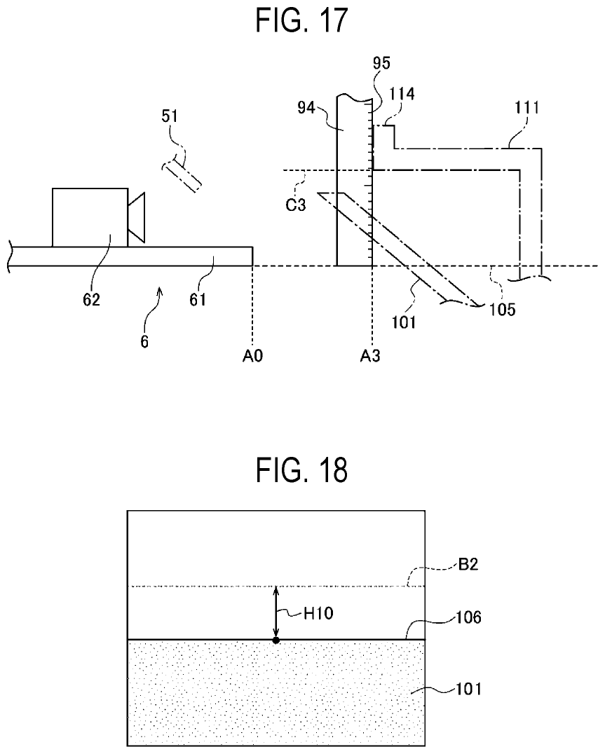

It is assumed that, when the cup 4 is normally assembled with respect to the upper guide part 111, the lower end of the opening wall 114 is disposed at a position separated away from the reference position A0 by A3 mm to the outside of the wafer W along the radial direction of the wafer W. In that case, as illustrated in FIG. 17, the operator disposes the scale 94 at the position separated away from the reference position A0 by A3 mm such that the edge 95 extends in the vertical direction. Then, the operator acquires the image data of the scale 94 by the second camera 62. In this image data, a gradation indicating the height of the lower end of the opening wall 114 (referred to as “reference height C3”) when the assembly of the cup 4 is normal is detected, and the pixel at the height at which the gradation is captured is determined as a reference height pixel B3. In addition, a pixel pitch (pixel pitch 3) is acquired from the scale 94 in the image data.

The reference height pixels B1 to B3 and the pixel pitches 1 to 3 acquired as described above are stored in the memory 84 of the arithmetic device 8 by the operator. The memory 84 corresponds to the first storage part, the pixel pitches 1 and 2 correspond to the conversion information for the cup, and the pixel pitch 3 corresponds to the conversion information for the nozzle. When plural inspection wafers 6 are used, it is preferable to acquire the reference height pixels B1 to B3 and the pixel pitches 1 to 3 for each inspection wafer 6 and store the reference height pixels B1 to B3 and the pixel pitches 1 to 3 in the memory 84 in consideration of the difference in operation accuracy or assembly accuracy between the inspection wafers 6.

In addition, a method of obtaining the pixel pitches 1 to 3 from the number of pixels between adjacent gradations of the scale 94 in the image is used, but the present disclosure is not limited thereto. As an example of another method, there is a method using the structure of the cup 4 in the image. Since the method is based on the position of an actual inspection target, the method has an effect of further improving the accuracy of the measurement result. Specifically, in the method of acquiring the pixel pitch 2, the lifting mechanism 36 is controlled by the controller 20 such that the lifting pins 35 move upward by 1 mm in the state in which the inspection wafer 6 is placed thereon, and before and after the operation of moving upward, the second camera 62 is controlled by the controller 20 to image the upper end 106 of the intermediate guide part 101. Then, it is possible to obtain the pixel pitch 2 by specifying how many pixels the position of the upper end 106 has changed in the two images acquired before and after the operation of moving upward. Although the acquisition of the pixel pitch 2 has been described representatively, it is possible to acquire the other pixel pitches from the images obtained by changing the height of the inspection wafer 6 with respect to the inspection target.

The inspection performed after performing the above-mentioned pre-preparation will be described focusing on the differences from the inspection described in the first embodiment. First, the inspection wafer 6 is transported to the resist film forming module 3 and attracted to the spin chuck 31. Then, the solvent supply nozzle 51B moves to the processing position, and intermittent rotation of the spin chuck 31 and imaging by the second camera 62 when the rotation is stopped are performed.

Hereinafter, a description will be made with reference to the schematic view of FIG. 18. FIG. 18 is a schematic view illustrating one of acquired image data, and the intermediate guide part 101 in the image is illustrated with dots. Illustration of the members other than the intermediate guide part 101 is omitted. First, the upper end 106 of the intermediate guide part 101 in the image data is detected, and the number of pixels between the pixel at which the upper end 106 is captured and the reference height pixel B2 (denoted as H10 in the drawing) is detected.

Then, the number of detected pixels is multiplied by the pixel pitch 2, so that the difference in height between the upper end 106 and the reference height C2 is calculated. This height difference (the distance between the upper end 106 and the reference height C2) is calculated from each acquired image data, and it is determined whether or not the height difference falls within the preset permissible range. Then, for example, when respective height differences are determined to fall within the permissible range, the height of the intermediate guide part 101 is regarded as normal, and when any of respective height differences does not fall within the permissible range, the height of the intermediate guide part 101 is regarded as abnormal.

In addition, the lower end of the opening wall 114 of the upper guide part 111 in each image data is detected, the number of pixels between the pixel at the lower end and the reference height pixel B3 is detected, and the number of pixels is multiplied by the pixel pitch 3, so that the difference in height between the lower end of the opening wall 114 and the reference height C3 is calculated. When all of the height differences obtained from respective image data of the upper guide part 111 fall within the permissible range, the height of the upper guide part 111 is regarded as normal, and when any of respective height differences does not fall within the permissible range, the height of the upper guide part 111 is regarded as abnormal.

Then, image data in which the solvent supply nozzle 51B is captured is selected from among respective acquired image data. The number of pixels between the pixel at the lower end of the solvent supply nozzle 51B and the reference height pixel B1 in the selected image data is multiplied by the pixel pitch 1, so that the difference in height between the lower end of the solvent supply nozzle 51B and the reference height C1 is calculated. When this difference in height does not fall within the permissible range, the height of the solvent supply nozzle 51 is regarded as abnormal.

As described above, according to the second embodiment, the reference height and the pixel pitch are acquired in advance as pre-preparation data for each inspection target. Then, since the inspection is performed based on the pre-preparation data and the image data acquired by transporting the inspection wafer 6 to the resist film forming module 3, it is possible to perform abnormality determination with high accuracy for the height of each of the solvent supply nozzle 51B, the intermediate guide part 101, and the upper guide part 111, which are inspection targets.

In the above-described inspection examples, the upper end of the inner peripheral edge of the inclined wall 103 is set as a detection target in the image of the intermediate guide part 101, the lower end of the inner peripheral edge of the opening wall 114 is set as the detection target in the image of the upper guide part 111, and the detection targets are compared with the reference heights for these detection targets. However, portions of the acquired image that are relatively easy to detect in the acquired images may be set as the detection targets. Therefore, the present disclosure is not limited to using the above-described portions as detection targets. For example, with respect to the upper guide part 111, the upper end of the inner peripheral edge of the opening wall 114 may be set as a detection target, and the abnormality determination may be performed by comparing the upper end with the reference height corresponding to the upper end.

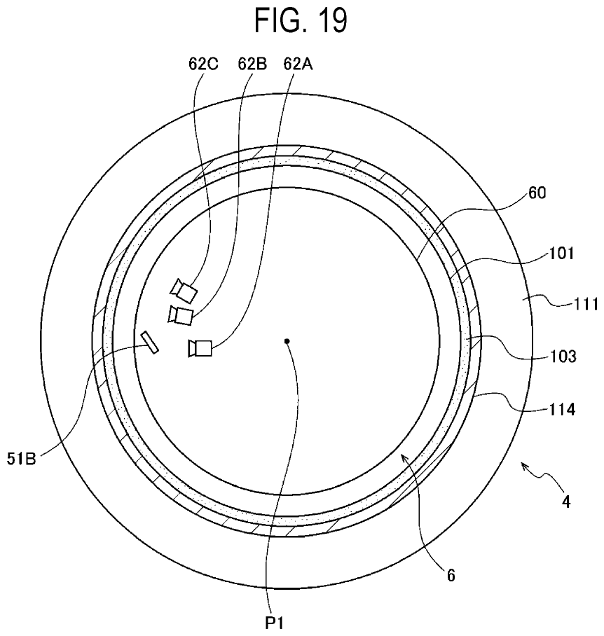

The plan view of FIG. 19 illustrates another configuration example of the inspection wafer 6 used in the second embodiment. The plan view of FIG. 19 illustrates an example in which three second cameras 62 are provided in the main body 60 of the inspection wafer 6, and are distinguished from each other as cameras 62A, 62B, and 62C for convenience of description. The focal lengths of the cameras 62A to 62C are the same. The radial positions of the cameras 62A to 62C in the main body 60 are different from each other, and in a plan view, the cameras 62A, 62B, and 62C are closest to the center P1 of the main body 60 of the inspection wafer 6 in this order.

Based on the image data from the cameras 62A, 62B, and 62C, abnormality determination is performed for each of the heights of the solvent supply nozzle 51B, the intermediate guide part 101, and the upper guide part 111. That is, the cameras 62A, 62B, and 62C are arranged such that an appropriate depth of field is obtained according to the position of each of the solvent supply nozzle 51B, the intermediate guide part 101, and the opening wall 114 of the upper guide part 111, which are the inspection targets. In this way, a camera may be provided for each inspection target. In FIG. 19, dots are indicated on the inclined wall 103 of the intermediate guide part 101 and hatching is added to the opening wall 114 of the upper guide part 111 in order to facilitate understanding of the drawing.

As described above with reference to the configuration of the second camera 62 of the first embodiment, for each of the cameras 62A to 62C, a height changing portion capable of appropriately adjusting the height with respect to the main body 60 may be provided such that, when an object to be imaged is at a normal height, the object to be imaged is positioned in the height center portion of the image. As described with reference to FIGS. 16 and 18, when the height of the upper end of the intermediate guide part 101 is compared with the reference height pixel B2, for example, the camera 62B may be disposed at a position at which the reference height pixel B2 is positioned in the height center portion of the image. When comparing the height of the lower end of the opening wall 114 of the upper guide part 111 with the reference height pixel B3 as described with reference to FIG. 17, for example, the camera 62C may be disposed at a position at which the reference height pixel B3 is positioned in the height center portion of the image.

The embodiments disclosed herein are exemplary in all respects and are not restrictive. The above-described embodiments may be omitted, replaced, modified, and combined in various forms without departing from the scope and spirit of the appended claims.

The present disclosure can prevent occurrence of defects in processing by disposing a nozzle or a cup at an inappropriate position with respect to a substrate in a substrate processing apparatus for liquid-processing the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An information acquisition system for acquiring information about a substrate processing apparatus which includes a substrate holder configured to hold and rotate a substrate, a nozzle configured to supply a processing liquid to a surface of the substrate which is rotating, and a cup surrounding the substrate held by the substrate holder, the information acquisition system comprising:
an information acquisition body held in place of the substrate by the substrate holder and including an imaging part configured to image the cup and acquire image data; and
an acquisition part configured to acquire information about a height of the cup based on the image data.

2. The information acquisition system of claim 1, wherein the cup includes a side wall and an annular protrusion body formed to protrude from the side wall toward a center of the cup,
wherein the imaging part is further configured to image an inner peripheral end of the annular protrusion body, and
wherein information about a height of the annular protrusion body is acquired as the information about the height of the cup.

3. The information acquisition system of claim 2, further comprising:
a first storage part configured to store conversion information for the cup for converting a number of pixels between a preset reference height in the image data acquired by the information acquisition body held by the substrate holder and the inner peripheral end of the annular protrusion body into a distance,
wherein the acquisition part is further configured to acquire information about the height of the annular protrusion body based on the conversion information for the cup.

4. The information acquisition system of claim 3, wherein the annular protrusion body includes an intermediate annular body that protrudes from a height below an upper end of the side wall, and
wherein the information about the height of the annular protrusion body includes information about a height of the intermediate annular body.

5. The information acquisition system of claim 2, wherein the imaging part is provided on the information acquisition body such that the inner peripheral end of the annular protrusion body at a position set to be imaged by the imaging part is positioned at a height center portion of the image acquired by the imaging part.

6. The information acquisition system of claim 1, wherein the imaging part is provided such that a height of the imaging part in the information acquisition body is adjustable.

7. The information acquisition system of claim 1, wherein the cup includes a lower member provided below the substrate held by the substrate holder and a protrusion provided on the lower member to protrude upward,
wherein the imaging part is further configured to image a top surface of the protrusion, and
wherein the acquisition part is further configured to acquire a first distance between the substrate and the protrusion as the information about the height of the cup.

8. An information acquisition system for acquiring information about a substrate processing apparatus which includes a substrate holder configured to hold and rotate a substrate, a nozzle configured to supply a processing liquid to a surface of the substrate which is rotating, and a cup surrounding the substrate held by the substrate holder, the information acquisition system comprising:
an information acquisition body held in place of the substrate by the substrate holder and including an imaging part configured to image the nozzle and acquire image data; and
an acquisition part configured to acquire a second distance between the substrate and the nozzle based on a number of pixels between the nozzle in the image data and a preset reference height in the image data.

9. The information acquisition system of claim 8, further comprising:
a second storage part configured to store:
a third distance which is a difference between the surface of the substrate held by the substrate holder and a height corresponding to the reference height in the image data acquired by the information acquisition body held by the substrate holder; and
conversion information for the nozzle for converting a number of pixels between the nozzle and the reference height in the image data into a distance,
wherein the acquisition part is further configured to acquire the second distance based on the third distance and the conversion information for the nozzle.

10. The information acquisition system of claim 8, further comprising:
a second lifting mechanism configured to change a relative height between the substrate holder and the nozzle according to the second distance.

11. The information acquisition system of claim 8, wherein the nozzle is further configured to supply the processing liquid to a peripheral edge of the substrate by ejecting the processing liquid in a direction inclined with respect to a vertical direction.

12. An arithmetic device for acquiring information about a substrate processing apparatus which includes a substrate holder configured to hold and rotate a substrate, a nozzle configured to supply a processing liquid to a surface of the substrate which is rotating, and a cup surrounding the substrate held by the substrate holder, the arithmetic device comprising:
a storage part configured to store image data acquired by an imaging part included in an information acquisition body held in place of the substrate by the substrate holder in order to image the cup; and
an acquisition part configured to acquire information about a height of the cup based on the image data.

13. An information acquisition method for acquiring information about a substrate processing apparatus which includes a substrate holder configured to hold and rotate a substrate, a nozzle configured to supply a processing liquid to a surface of the substrate which is rotating, and a cup surrounding the substrate held by the substrate holder, the information acquisition method comprising:
holding an information acquisition body by the substrate holder in place of the substrate;
acquiring image data by imaging the cup using an imaging part included in the information acquisition body; and
acquiring information about a height of the cup by an acquisition part based on the image data.

14. The information acquisition method of claim 13, wherein the cup includes a side wall and an annular protrusion body formed to protrude from the side wall toward a center of the cup,
wherein the acquiring the image data includes imaging an inner peripheral end of the annular protrusion body to acquire the image data, and
wherein, in the acquiring the information about the height of the cup, information about a height of the annular protrusion body is acquired.

15. The information acquisition method of claim 14, wherein the acquiring the information about the height of the cup includes:
acquiring the image data; and
using conversion information for the cup for converting a number of pixels between a reference height in the image data and the inner peripheral end of the annular protrusion body into a distance to acquire the distance, and
wherein the information acquisition method further comprises:
acquiring the conversion information for the cup by imaging a jig before imaging the inner peripheral end of the annular protrusion body, and by using image data of the jig.

16. The information acquisition method of claim 15, wherein the cup includes a lower member provided below the substrate held by the substrate holder and a protrusion provided on the lower member to protrude upward,
wherein the acquiring the image data includes imaging a top surface of the protrusion, and
wherein the acquiring the information about the height of the cup includes acquiring a first distance between the substrate and the protrusion.
